(19) United States
(12) Patent Application Publication
(10) Pub. No.: US 2024/0421186 A1
(43) Pub. Date: Dec. 19, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ta-Chun LIN, Hsinchu (TW); Shih-Hsun Chang, Hsinchu (TW)

(73) Assignee: Taiwan Semiconductor Manufacturing Company, Ltd., Hsinchu (TW)

(21) Appl. No.: 18/334,350

(22) Filed: Jun. 13, 2023

(51) Int. Cl. H01L 29/06; H01L 21/8238; H01L 27/092; H01L 29/08; H01L 29/423; H01L 29/66; H01L 29/775; H01L 29/786

(52) U.S. Cl. CPC H01L 29/0673; H01L 21/823807; H01L 21/823878; H01L 27/092; H01L 29/0847; H01L 29/42392; H01L 29/66439; H01L 29/66545; H01L 29/775; H01L 29/78696

(57) ABSTRACT

A semiconductor device and a manufacturing method thereof are provided. The semiconductor device includes semiconductor nanosheets vertically stacked upon one another and disposed above a semiconductor substrate, a gate structure surrounding each of the semiconductor nanosheets, and source/drain regions disposed over the semiconductor substrate and laterally abutting the semiconductor nanosheets. The semiconductor nanosheets serve as channel regions, and a topmost semiconductor nanosheet most distanced from the semiconductor substrate is thinner than an underlying semiconductor nanosheet between the topmost semiconductor nanosheet and the semiconductor substrate.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 14 illustrate schematic cross-sectional views of intermediate steps during a process for forming a semiconductor device, in accordance with some embodiments.

FIG. 15 illustrates a schematic cross-sectional view of a semiconductor device, in accordance with some embodiments.

FIGS. 16 through 19 illustrate schematic cross-sectional views of intermediate steps during a process for forming a semiconductor device, in accordance with some embodiments.

FIGS. 20 and 21 illustrate schematic cross-sectional views of intermediate steps during a process for forming a semiconductor device, in accordance with some embodiments.

FIG. 22 illustrates a schematic cross-sectional view of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the disclosure describe methods for forming a semiconductor device (or a portion of a nanostructure transistor device) with improved performance, reduced short channel effects, and reduced leakage currents. The nanostructure transistor device (also referred to as a gate-all-around (GAA) transistor device) may include a gate structure wrapping around the perimeter of one or more nanostructures (i.e. channel regions) for improved control of channel current flow. The embodiments are not limited in this context. The semiconductor device may be included in microprocessors, memories, and/or other ICs. It is understood that the structures illustrated in the drawings are simplified for a better understanding of the concepts of the present disclosure. In addition, although the figures illustrate the structure of the semiconductor device, it is understood the semiconductor device may be part of an IC that further includes a number of other devices such as resistors, capacitors, inductors, fuses, etc.

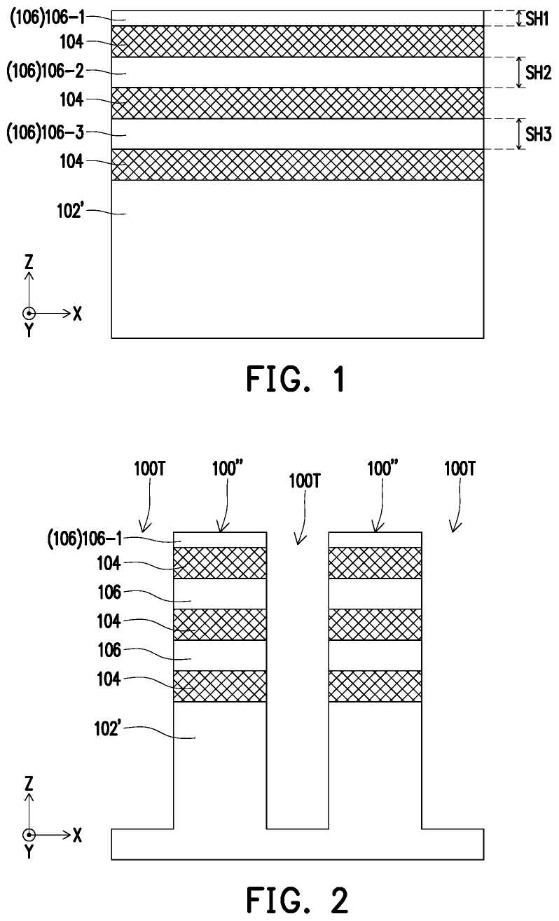

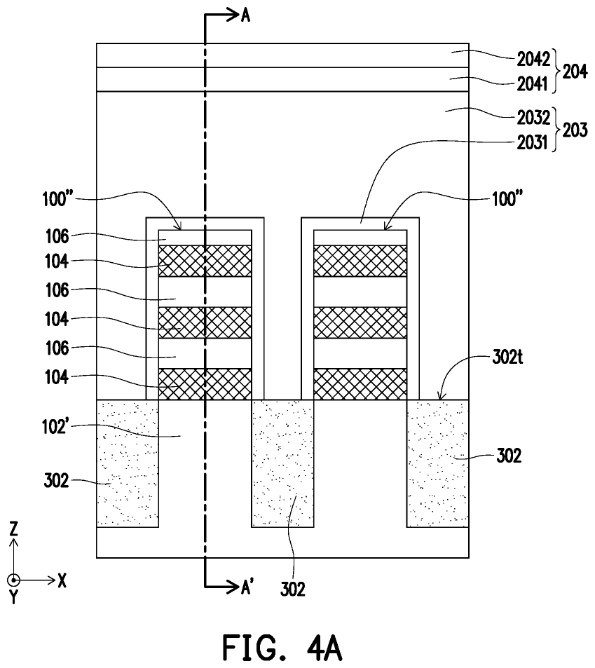

FIGS. 1 through 14 illustrate schematic cross-sectional views of intermediate steps during a process for forming a semiconductor device, according to some embodiments. For clarity of illustrations, in the drawings are illustrated the orthogonal axes (X, Y and Z) of the Cartesian coordinate system according to which the views are oriented. It should be noted that FIGS. 1-4A are cross-sectional views of the structure taken at the X-Z plane, FIG. 4B is a cross-sectional view of the structure illustrated in FIG. 4A taken along the line A-A′, and FIGS. 4B, and 5-14 are cross-sectional views taken at the Y-Z plane and illustrating the following steps of forming a semiconductor device. Although FIGS. 1-14 are described as a series of acts, these acts are not limiting in that the order of the acts can be altered in other embodiments, and the methods disclosed are also applicable to other structures. In alternative embodiments, some acts that are illustrated and/or described may be omitted in whole or in part.

Referring to FIG. 1, a stack of first semiconductor layers 104 and second semiconductor layers 106 (e.g., 106-1, 106-2, and 106-3) may be formed on a semiconductor substrate 102′. In some embodiments, the semiconductor substrate 102′ includes a crystalline silicon substrate or a bulk silicon substrate (e.g., wafer). In some embodiments, the semiconductor substrate 102′ is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102′ includes a silicon-on-insulator (SOI) substrate or other suitable substrate. The semiconductor substrate 102′ may include various doped regions (not individually shown) doped with p-type or n-type dopants, where the doped regions may be configured for an n-type region, or alternatively, configured for a p-type region.

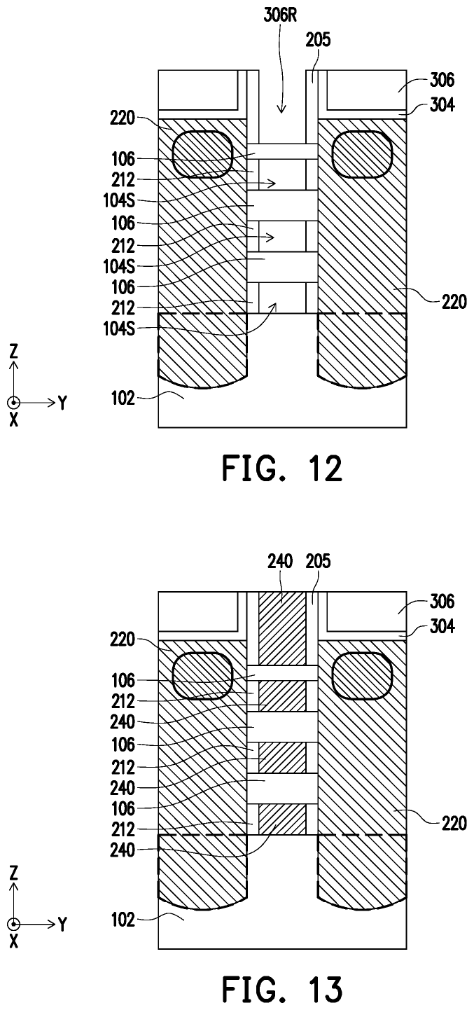

The first semiconductor layers 104 and the second semiconductor layers 106 may be alternately stacked upon one another (e.g., along the Z-direction) to form a stack. In some embodiments, the first semiconductor layers 104 and the second semiconductor layers 106 are grown from the semiconductor substrate 102′. For example, each of the first semiconductor layers 104 and the second semiconductor layers 106 is grown by a molecular beam epitaxy (MBE) process, a chemical vapor deposition (CVD) process, or any suitable growth process. The first semiconductor layers 104 may be considered sacrificial layers in the sense that they are removed in the subsequent process (see FIG. 12). In some embodiments, the bottommost one of the first semiconductor layers 104 is formed on the semiconductor substrate 102′, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102′). In some embodiments, the second semiconductor layer 106 may be the topmost layer (or the layer most distanced from the semiconductor substrate 102′) of the stack and is viewed as the topmost second semiconductor layer 106t. It should be noted that the number of the first semiconductor layers 104 and the number of the second semiconductor layers 106 illustrated herein are examples and construe no limitation in the disclosure. The stack may include two of the first semiconductor layers and two of the second semiconductor layers or may include more than three of the first semiconductor layers and more than three of the second semiconductor layers.

The first semiconductor layers 104 and the second semiconductor layers 106 may have different materials (or compositions) that provide for different oxidation rates and/or different etch selectivity between the layers. For example, the second semiconductor layers 106 are formed of the same material as the semiconductor substrate 102′, while the first semiconductor layers 104 may be formed of a different material which is selectively removed with respect to the material of the semiconductor substrate 102′ and the second semiconductor layers 106. In some embodiments, the material of the first semiconductor layers 104 includes silicon germanium. In some embodiments, the material of the second semiconductor layers 106 include silicon, where each of the second semiconductor layers 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets that are considered as channel regions in the semiconductor device. The terms “semiconductor nanosheets” and “channel regions/layers” may be used interchangeably herein.

With continued reference to FIG. 1, the thickness of each of the second semiconductor layers 106 may range from few nanometers to few tens of nanometers. The topmost second semiconductor layer 106-1 may have a thickness SH1 different from a thickness SH2 of the middle second semiconductor layer 106-2 and a thickness SH3 of the bottommost second semiconductor layer 106-3. The topmost second semiconductor layer 106-1 may be the thinnest layer among the second semiconductor layers 106. For example, the thickness SH1 is less than the thickness SH2 and the thickness SH3. In some embodiments, a difference between the thickness SH3 of the bottommost second semiconductor layer 106-3 and the thickness SH1 of the topmost second semiconductor layer 106-1 is in a range of about 0.5 nm to about 4.0 nm, although other differences are within the contemplated scope of the disclosure.

Referring to FIG. 2 and with reference to FIG. 1, a portion of the stack of first semiconductor layers 104 and second semiconductor layers 106 along with the underlying portion of the semiconductor substrate 102′ may be removed to form trenches 100T, thereby defining a fin structure 100″ between adjacent trenches 100T. The fin structure 100″ may be formed by patterning the stack of first semiconductor layers 104 and second semiconductor layers 106 and the underlying semiconductor substrate 102′ by using, e.g., lithography and etching, or other suitable patterning processes. For example, a mask layer (not shown) is formed and patterned on the topmost second semiconductor layer 106-1, and the fin structure 100″ is formed by etching trenches 100T at portions of the stack of first semiconductor layers 104 and second semiconductor layers 106 and the underlying semiconductor substrate 102′ that are accessibly exposed by the mask layer. After forming the trenches 100T, the mask layer may be removed to reveal the topmost second semiconductor layer 106-1. The trenches 100T may be parallel strips (when viewed from the top) elongated along the Y-direction and distributed along the X-direction.

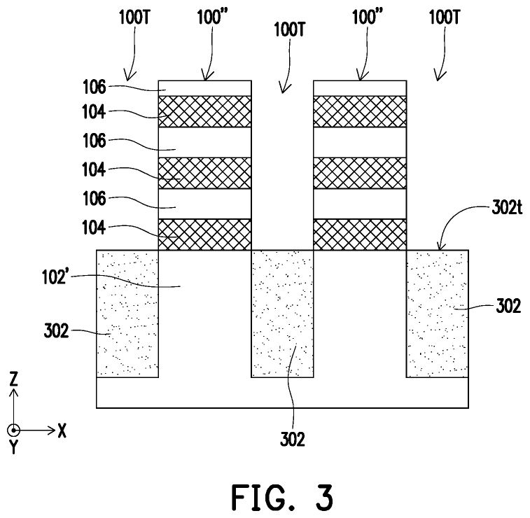

Referring to FIG. 3 and with reference to FIG. 2, a plurality of isolation structures 302 (also referred to as shallow trench isolation (STI) structures) may be formed in lower portions of the trenches 100T. For example, the isolation structures 302 extend at opposing sides of a lower portion of the semiconductor substrate 102′. In some embodiments, each of the isolation structures 302 is disposed between adjacent two of the fin structures 100″ and covers a sidewall of a lower portion of the respective fin structure 100″. The top surface 302t of the respective isolation structure 302 may be a flat surface, a curved (e.g., convex or concave) surface, or a combination thereof. The isolation structures 302 may be formed of an insulation material (e.g., an oxide, a Si-based oxide (e.g., SiOC, SiOCN, or the like), a nitride, the like, any other suitable material, or combinations thereof) which may electrically isolate neighboring fin structures 100″ from each other.

Referring to FIGS. 4A and 4B with reference to FIG. 3, a dummy gate structure 203 and a mask layer 204 overlying the dummy gate structure 203 may be formed on the fin structures 100″. For example, the dummy gate structure 203 includes a dummy dielectric layer 2031 formed on the fin structures 100″ and a dummy gate layer 2032 formed on the dummy dielectric layer 2031. In some embodiments, the dummy dielectric layer 2031 covers the top surfaces 302t of the isolation regions 302 and may extend between the dummy gate layer 2032 and the isolation regions 302. The dummy dielectric layer 2031 may include silicon oxide, silicon nitride, a combination thereof, or the like, and may be deposited or thermally grown according to acceptable techniques. The dummy gate layer 2032 may be a conductive or non-conductive material, and may be selected from a group including amorphous silicon, polysilicon, poly-crystalline silicon-germanium, metallic oxides, and metals, and may be formed by using physical vapor deposition (PVD), CVD, sputtering, or other suitable techniques.

The mask layer 204 formed on the dummy gate layer 2032 may be a single mask layer or include multiple sublayers formed of different materials including silicon nitride, silicon oxynitride, or the like. In the illustrated embodiment, the mask layer 204 includes a first mask sublayer 2041 overlying the dummy gate layer 2032 and a second mask sublayer 2042 overlying the first mask sublayer 2031. For example, a layer of mask material is initially formed and then patterned using acceptable lithography and etching techniques to form the mask layer 204. Next, the pattern of the mask layer 204 may be transferred to the underlying dummy gate and dielectric materials to form the dummy gate layer 2032 and the dummy dielectric layer 2031, respectively. For example, the dummy gate structure 203 has a lengthwise direction along the X-direction which is perpendicular to the lengthwise direction (e.g., the Y-direction) of the respective fin structure 100″.

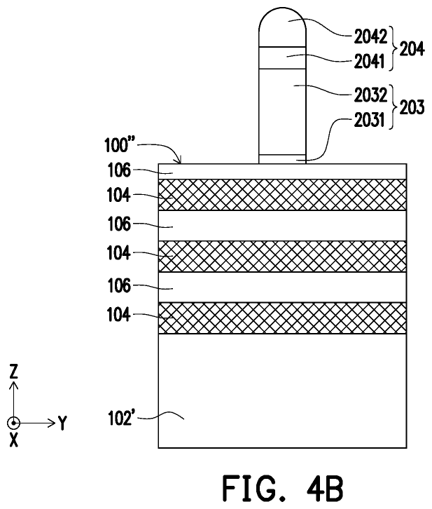

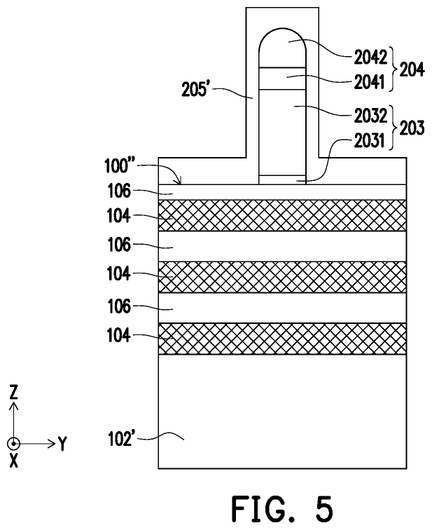

Referring to FIG. 5 and with reference to FIG. 4B, a gate spacer layer 205′ may be conformally formed on the dummy gate structure 203, the mask layer 204, and portions of the fin structure 100″ exposed by the dummy gate structure 203 and the mask layer 204. In the X-Z cross section (not shown), the gate spacer layer 205′ may further extend to cover sidewalls of the respective fin structure 100″. The gate spacer layer 205′ may be a single layer or may include multiple sublayers formed of different materials including silicon oxide, silicon nitride, silicon oxynitride, or the like. The gate spacer layer 205′ may be deposited by thermal oxidation or deposited by CVD, ALD, etc.

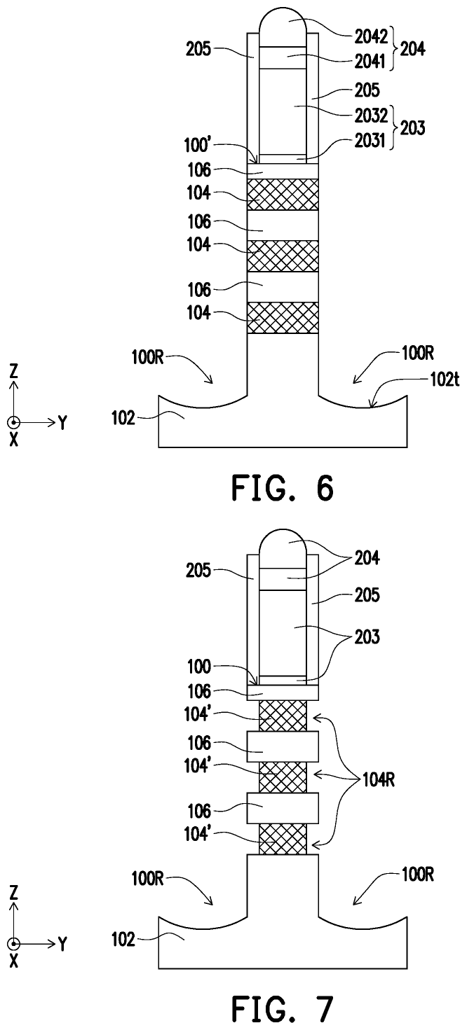

Referring to FIG. 6 and with reference to FIG. 5, a portion of the gate spacer layer 205′ covering an upper portion of the mask layer 204 and the top surface of the respective fin structure 100″ may be removed to form a gate spacer 205. For example, the gate spacer layer 205′ is partially removed using an etching process to form the gate spacer 205, where the gate spacer 205 may be disposed on the sidewall of the dummy gate structure 203 and may extend to partially (or fully) cover the sidewall of the mask layer 204. In some embodiments, the top surface and the upper sidewall of the second mask sublayer 2042 are exposed by the gate spacer 205. The gate spacer 205 may act to self-align subsequently-formed source/drain (S/D) regions, as well as to protect sidewalls of the respective fin structure 100″ during subsequent processing.

In some embodiments, a portion of the respective fin structure 100″ and a portion of the semiconductor substrate 102′ underlying the portion of the respective fin structure 100″ are removed to form recesses 100R and a respective etched fin structure 100′ between two adjacent recesses 100R. S/D regions will be subsequently formed in the recesses 100R, and the recesses 100R may be referred to as S/D recesses. The recesses 100R may be formed by etching the gate spacer layer 205′, the underlying fin structures 100″, and the underlying semiconductor substrate 102′ using etching processes, such as anisotropic etching, or the like. A single etching process or multiple etching processes may be employed. In some embodiments, outer sidewalls of the gate spacer 205 are substantially aligned with sidewalls of the etched fin structure 100′. The respective recess 100R may further extend into the underlying semiconductor substrate 102′ to form a semiconductor substrate 102 having exposed top surfaces 102t, where the top surfaces 102t may be a flat surface, a curved (e.g., concave) surface, or combinations thereof, depending on the etching process.

Referring to FIG. 7 and with reference to FIG. 6, portions of the first semiconductor layers 104 exposed by the recesses 100R may be removed in the lateral direction (e.g., the Y-direction) to form a respective etched fin structure 100 having etched first semiconductor layers 104′. The removal may be performed by using, e.g., isotropic etching or the like. For example, the etchant of the selective etching process is chosen so that the portions of the first semiconductor layers 104 are removed to form lateral recesses 104R, while the second semiconductor layers 106 remain substantially intact after the etching. The respective etched first semiconductor layer 104′ may be laterally recessed from the sidewalls of the underlying (or overlying) second semiconductor layer 106. Although sidewalls of the etched first semiconductor layers 104′ adjacent to the lateral recesses 104R are illustrated as being straight in FIG. 7, the sidewalls of the etched first semiconductor layers 104′ may be tilted, concave, or convex.

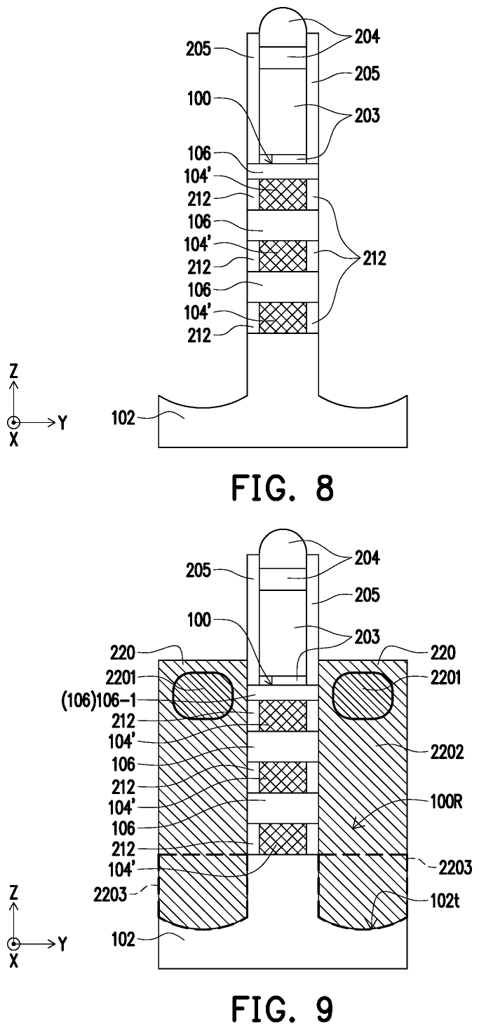

Referring to FIG. 8 and with reference to FIG. 7, inner spacers 212 may be formed in the lateral recesses 104R. For example, the inner spacers 212 are formed along the etched ends of each of the etched first semiconductor layers 104′ and along respective ends (along the Y-direction) of each of the etched first semiconductor layers 104′ and the second semiconductor layers 106. The inner spacers 212 may be formed of silicon nitride, silicon carbon-nitride, silicon-carbon-oxynitride, or any other type of dielectric material, and may be deposited using, e.g., a conformal deposition process and subsequent etching back to remove excess spacer material on the sidewalls of the etched fin structure 100 and on the exposed surface of the semiconductor substrate 102. In some embodiments, the inner spacers 212 are formed of a material different from the gate spacer 205. The gate spacer 205 may serve as an etch mask when removing excess spacer material, and thus the outer sidewall of the gate spacer 205 may be substantially aligned with outer sidewalls of the underlying second semiconductor layers 106 and outer sidewalls of the inner spacers 212.

Referring to FIG. 9 and with reference to FIG. 8, epitaxial structures 220 may be epitaxially grown in the recesses 100R using a process such as CVD, ALD, MBE, or the like. The epitaxial structures 220 grown on the semiconductor substrate 102 may have a bottom surface conformally coupled to the exposed top surfaces 102t of the semiconductor substrate 102. In some embodiments, the epitaxial structures 220 are coupled to the outer sidewalls of the second semiconductor layers 106 and the inner spacers 212 along the Y-direction. In some embodiments where the semiconductor substrate 102 has a concave top surface, the bottom surface of the respective epitaxial structure 220 may be a convex surface corresponding to the exposed top surfaces 102t. Although the upper surfaces of the epitaxial structures 220 are illustrated as planar surfaces in the Y-Z cross section, it should be understood that in the perspective view, the upper surfaces of the epitaxial structures 220 have facets which expand laterally outward along the Y-direction beyond the sidewalls of the dummy gate structures 203. Each dummy gate structure 203 may be disposed between respective neighboring pairs of the epitaxial structures 220. The gate spacer 205 may be used to separate the epitaxial structures 220 from the dummy gate structure 203 by a lateral distance so that the epitaxial structures 220 do not short out with subsequently-formed gate structures.

Each epitaxial structure 220 may include silicon germanium, indium arsenide, indium gallium arsenide, indium antimonide, germanium arsenide, germanium antimonide, indium aluminum phosphide, indium phosphide, any other suitable material, or combinations thereof. The epitaxial structures 220 may be doped with a conductive dopant to form S/D regions. For example, the S/D dopant may be formed by in-situ epitaxially growth, ion implantation, solid phase diffusion, a combination thereof, etc., where the ion implantation process or the solid phase diffusion process may be processed after epitaxially growth or after the etching of FIG. 12. It should be noted that S/D region(s) may refer to a source or a drain, individually or collectively dependent upon the context. The terms “epitaxial structures” and “S/D regions” are used interchangeably herein. The structure shown herein may be in the n-type region (e.g., the NMOS region) or the p-type region (e.g., the PMOS region). In some embodiments, the dopant of the epitaxial structures 220 grown in the n-type region (not individually shown) may be donor-type species, such as phosphorus, arsenic, antimony for silicon-based transistor. In some embodiments, the dopant of the epitaxial structures 220 grown in the p-type region (not individually shown) may be acceptor-type species, such as boron, aluminum, gallium for silicon-based transistor.

With continued reference to FIG. 9, the respective epitaxial structure 220 may have different doping levels. For example, the respective epitaxial structure 220 includes a first region 2201 doped with a higher dopant concentration than a second region 2202 below the first region 2201, where the first region 2201 is in proximity to (or laterally adjacent to) the topmost second semiconductor layer 106-1, and the second region 2202 is in proximity to (or laterally adjacent to) the other second semiconductor layers 106. The first region 2201 may be viewed as a heavily doped region to reduce resistance and enhance contact performance. In some embodiments, the respective epitaxial structure 220 includes a bottommost region 2203 between the second region 2202 and the semiconductor substrate 102 and laterally adjacent to the raised portion of the semiconductor substrate 102. The bottommost region 2203 may be an undoped region (or substantially dopant-free region). Alternatively, the bottommost region 2203 is omitted and replaced with the second region 2202. In FIG. 9, the bottommost region 2203 is illustrated in the dashed line to indicate it may or may not exist.

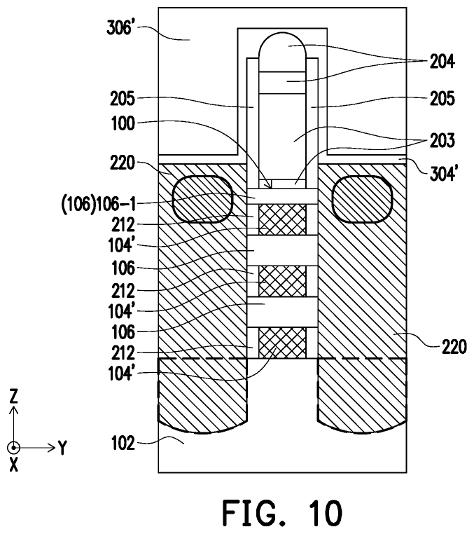

Referring to FIG. 10 and with reference to FIG. 9, a first interlayer dielectric (ILD) material layer 306′ may be formed over the structure illustrated in FIG. 9. The first ILD material layer 306′ may be formed of a dielectric material including phosphosilicate glass (PSG), borosilicate glass (BSG), boron-doped phosphosilicate glass (BPSG), undoped silicate glass (USG), or the like, and may be deposited by any suitable method, such as CVD, plasma-enhanced CVD (PECVD), or the like. In some embodiments, an etch stop material layer 304′ is disposed between the first ILD material layer 306′ and the epitaxial structures 220, the mask layer 204, and the gate spacer 205. The etch stop material layer 304′ may include a dielectric material (e.g., silicon nitride, silicon oxide, silicon oxynitride, or the like), and may have a different etch rate than the material of the overlying first ILD material layer 306′.

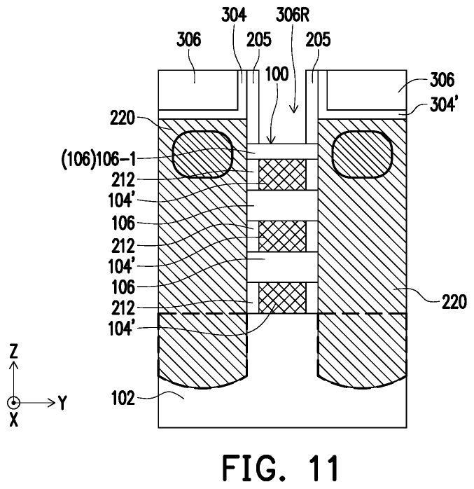

Referring to FIG. 11 and with reference to FIG. 10, one or more removal processes may be performed to form a first ILD layer 306, the etch stop layer 304 lining the first ILD layer 306, and a recess 306R accessibly revealing the topmost second semiconductor layer 106-1 of the respective etched fin structure 100. For example, the removal processes includes a planarization process performed on the first ILD material layer 306′. The planarization process may include CMP, grinding, etching, combinations thereof, or the like. During the planarization process, the mask layer 204 may be partially (or fully) removed. In some embodiments, the gate spacer 205 is also planarized during the planarization process. In some embodiments, one or more etching process may be performed after the planarization to remove the rest portion of the mask layer 204 (if exist) and the underlying dummy gate structure 203 so as to form the recess 306R. For example, reaction gas(es) may be used to selectively etch the dummy structure 203 at a faster rate than the first ILD material layer 306′, the etch stop material layer 304′, or the gate spacer 205.

Referring to FIG. 12 and with reference to FIG. 11, the etched first semiconductor layers 104′ may be removed by etching (e.g., isotropic etching or the like) to form recesses 104S. For example, using etchants which are selective to the materials of the etched first semiconductor layers 104′, while the second semiconductor layers 106, the first ILD layer 306, the etch stop layer 304, the gate spacer 205, and the inner spacers 212 remain relatively un-etched as compared to the etched first semiconductor layers 104′. During the removal process, the first ILD layer 306 and the etch stop layer 304 may protect the epitaxial structures 220. In some embodiments, after the removal of the etched first semiconductor layers 104′, respective bottom and top surfaces of each second semiconductor layers 106 and the top surface of the semiconductor substrate 102 may be exposed by the recesses 104S.

Referring to FIG. 13 and with reference to FIG. 12, a respective gate structure 240 may be formed around the second semiconductor layers 106 and fills the recesses 306R and 104S. The gate structure 240 may include a plurality of gate sections abutted to each other along the Z-direction in the X-Z plane. Each of the gate sections may extend not only along a horizontal plane (e.g., the X-Y plane), but also along a vertical direction (e.g., the Z-direction), and thus two adjacent ones of the gate sections may adjoin together to wrap around a corresponding one of the second semiconductor layers 106, where the second semiconductor layers 106 (also referred to as semiconductor nanosheets or channel layers) function as channel regions.

The gate structure 240 may include a gate dielectric layer (not individually shown), an interfacial layer (not individually shown) formed between each channel layer 106 and the gate dielectric layer, and a gate metal layer (not individually shown) wrapping around each channel layer 106 with the gate dielectric layer disposed therebetween. The gate dielectric layer may be one or more high-k dielectric material(s). The gate metal layer may include a stack of multiple metal materials. For example, one or more work function sublayers are interposed between the gate dielectric layer and the gate metal layer, where the work function sublayers may be formed separately for the n-type FET and the p-type FET which may use different metal layers. In some embodiments, excess materials of the gate structure 240 may be removed by a planarization process, so that the top surface of the topmost gate structure 240 is substantially leveled (e.g., coplanar) with top surfaces of the first ILD layer 306 and the etch stop layer 304, within process variations.

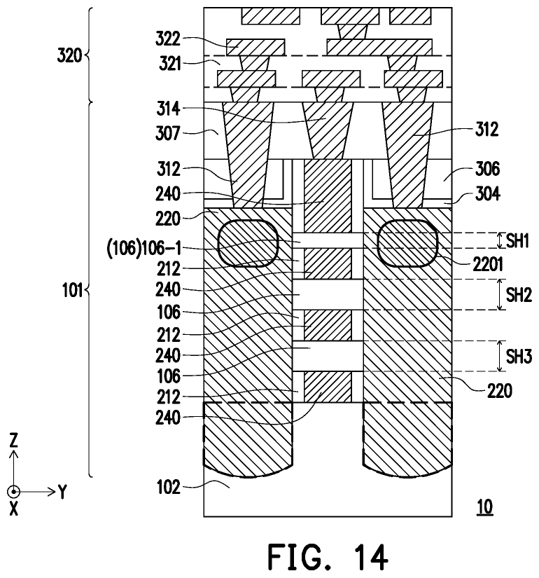

Referring to FIG. 14 and with reference to FIG. 13, a second ILD layer 307 may be formed on the first ILD layer 306. In some embodiments, S/D contacts 312 are formed to extend through the second ILD layer 307 and the underlying first ILD layer 306 so as to be electrically coupled to the epitaxial structures 220. In some embodiments, the respective S/D contact 312 is coupled to the first region 2201 in the corresponding S/D region 220. A gate contact 314 may be formed to extend through the second ILD layer 307 so as to be electrically coupled to the topmost gate structure 240. The second ILD layer 307 may be formed of a dielectric material such as PSG, BSG, BPSG, USG, or the like, and may be deposited by any suitable method, such as CVD, PECVD, or the like. In some embodiments, a planarization process is performed to level the top surfaces of the S/D contacts 312 and the gate contact 314.

In some embodiments, a front-side interconnect structure 320 including interconnect wirings 322 formed in an interconnect dielectric layer 321 may be formed on the second ILD layer 307, the S/D contacts 312, and the gate contact 314. The front-side interconnect structure 320 may be formed by back end of line (BEOL) processes and may be referred to as a BEOL interconnect structure. The material of the interconnect dielectric layer 321 may include a low-k dielectric material, an extra low-k (ELK) dielectric material, or the like. The interconnect wirings 322 may include conductive pads, conductive lines, and conductive vias interconnecting the layers of conductive lines, and may be formed through any acceptable process, such as a damascene process, a dual damascene process, or the like. For example, the conductive vias may extend through the interconnect dielectric layer 321 to provide vertical connections between layers of the conductive lines, and the bottommost conductive vias of the interconnect wirings 322 may be in physical and electrical contact with the S/D contacts 312 and the gate contact 314. The front-side interconnect structure 320 may be electrically coupled to the epitaxial structures 220 and the gate structures 240 through the S/D contacts 312 and the gate contact 314, respectively, to form functional circuits.

With continued reference to FIG. 14, a semiconductor device 10 includes a device layer 101 formed in/on the semiconductor substrate 102 and the front-side interconnect structure 320 formed on the device layer 101. The device layer 101 may include a plurality of active devices (e.g., transistors), the respective active device may include the epitaxial structure 220 (e.g., S/D regions), the second semiconductor layers 106 (e.g., the channel regions/layers), and the gate structures 240. Although the device layer 101 shown herein is described as including nano-FETs, other embodiments may include device layers including different types of transistors, such as planar FETs, FinFETs, thin film transistors (TFTs), or the like. The semiconductor device 10 may be a portion of a device wafer having a plurality of die regions. The device wafer may be singulated to separate a die from one another, and then the die may be packaged to form an IC package. The die may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a MEMS controller (e.g., application specific integrated circuit (ASIC)), a signal processing die (e.g., digital signal processing (DSP) die), a front-end die (e.g., analog front-end (AFE) dies), the like, or combinations thereof.

Still referring to FIG. 14, the first region 2201 of the respective S/D region 220 may be laterally adjacent to the topmost channel layer 106-1, and the topmost channel layer 106-1 may have the thickness SH1 less than the thickness SH2 and the thickness SH3 of the underlying channel layers 106. The structure illustrated in FIG. 14 may be in the n-type (e.g., NMOS) region or the p-type (e.g., PMOS) region. In some embodiments, the thickness SH1 of the topmost channel layer 106-1 in the n-type region and the thickness SH1 of the topmost channel layer 106-1 in the p-type region are different, and the difference therebetween may range from about 0.5 nm to about 2.0 nm, although other differences are within the contemplated scope of the disclosure. Alternatively, the thickness SH1 of the topmost channel layer 106-1 in the n-type region and the thickness SH1 of the topmost channel layer 106-1 in the p-type region are substantially equal. For example, the dopants from the region having higher doping concentration (e.g., the first region 2201) are readily diffused from the original implanted region into the channel region, causing short channel effects and undesirable leakage currents between the S/D regions. It is important to suppress the dopant lateral diffusion and keep the short channel effect under control. In the embodiment, by configuring the thinnest channel layer (e.g., the topmost channel layer 106-1) adjacent to the first region 2201, the short channel effect may be mitigated and the leakage current may be avoided, and the performance of the semiconductor device 10 may be improved.

FIG. 15 illustrates a schematic cross-sectional view of a semiconductor device, in accordance with some embodiments. Unless specified otherwise, like reference numerals in this embodiment represent like components in the embodiment shown in FIGS. 1 through 14 formed by like processes. Accordingly, the process steps and applicable materials may not be repeated herein.

Referring to FIG. 15 and with reference to FIG. 14, the difference between the semiconductor device 20 shown in FIG. 15 and the semiconductor device 10 shown in FIG. 14 lies in that a device layer 201 further includes bottom isolation structures 250 vertically interposed between the semiconductor substrate 102 and the S/D regions 220′ for prevention of leakage. The material of the bottom isolation structures 250 may include SiN, SiO₂, SION, SiCN, SiCON, SiCO, a high-k dielectric (e.g., HfO, AlO, etc.), compounds thereof, composites thereof, and/or combinations thereof. For example, the bottom isolation structures 250 are formed on the top surfaces 102t of the semiconductor substrate 102 after forming the inner spacers 212 as described in FIG. 8, and then the epitaxial structures (i.e. the S/D regions) 220′ are formed on the bottom isolation structures 250. The bottom isolation structures 250 may isolate the overlying S/D regions 220′ from the underlying semiconductor substrate 102. The respective bottom isolation structure 250 may have a substantially flat top surface 250t, and the epitaxial structures 220′ formed on the top surfaces 250t of the bottom isolation structure 250 may have a substantially flat bottom surfaces. The respective bottom isolation structure 250 may partially cover the sidewall of the bottommost inner spacer 212-3. For example, the upper portion of the sidewall of the bottommost inner spacer 212-3 is exposed by the neighboring bottom isolation structures 250. Since the bottom isolation structures 250 exposes at least a portion of the bottommost inner spacer 212-3, the removal process of the etched first semiconductor layers 104′ as described in FIG. 12 will not be affected.

With continued reference to FIG. 15, lower portions of the bottom isolation structures 250 may be replaced with undoped epitaxial structures 220D (or the epitaxial structures that are substantially dopant-free), in some embodiments. The materials of the bottom isolation structures 250 and the undoped epitaxial structures 220D are different. The undoped epitaxial structures 220D may be epitaxially grown on the semiconductor substrate 102, and the respective undoped epitaxial structure 220D may not extend upward beyond the bottom surface 212_3b of the bottommost inner spacer 212_3. In some embodiments, the top surface 220Dt of the respective undoped epitaxial structure 220D is substantially level with the bottom surface 212_3b of the bottommost inner spacer 212_3 as pictured in FIG. 15, slightly elevated above the bottom surface 212_3b, or slightly below the bottom surface 212_3b. The bottom isolation structures 250 may be formed on the top surfaces 220Dt of the undoped epitaxial structures 220D and laterally adjoin the bottommost inner spacer 212-3.

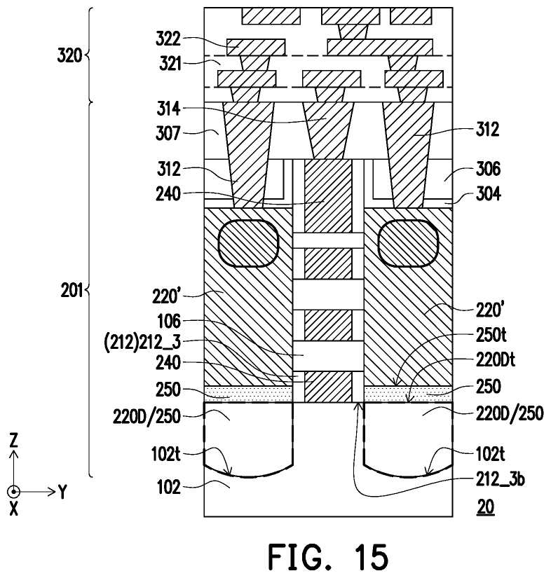

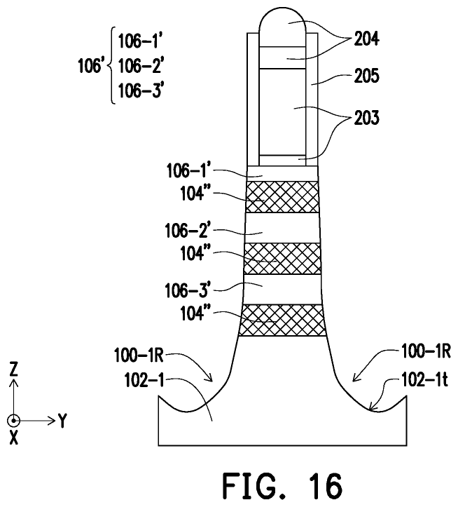

FIGS. 16-19 illustrate schematic cross-sectional views of intermediate steps during a process for forming a semiconductor device, in accordance with some embodiments. Unless specified otherwise, like reference numerals in this embodiment represent like components in the embodiment shown in FIGS. 1 through 14 formed by like processes. Accordingly, the process steps and applicable materials may not be repeated herein. In addition, although FIGS. 16-19 are described as a series of acts, these acts are not limiting in that the order of the acts can be altered in other embodiments, and the methods disclosed are also applicable to other structures. Alternatively, some acts that are illustrated and/or described may be omitted in whole or in part.

Referring to FIG. 16 and with reference to FIG. 6, the structure shown in FIG. 16 is similar to the structure shown in FIG. 6, except for the shape of the recesses 100-1R. The respective recess 100-1R may have a sloping shape in the cross-sectional view. For example, the respective recess 100-1R has a V-shaped (resembling the letter “V”) cross-sectional profile. The recesses 100-1R may be formed by one or more etching process (e.g., dry etching) to form the sloping shape. In some embodiments, the sidewall of the stack of the first and second semiconductor layers 104″ and 106′ is titled. For example, one or more layers of the first and second semiconductor layers 104″ and 106′ may have a non-vertical sidewall. In some embodiments, one or more layers of the first and second semiconductor layers 104″ and 106′ may have a trapezoidal profile having a wider bottom than top. The bottom of the respective recess 100-1R at the semiconductor substrate 102-1 may be etched to become a substantially V shape as compared to the recess 100R in FIG. 6 which is etched to have a substantially U shape. For example, the etched top surface 102-1t of the semiconductor substrate 102-1 is a concave surface and may have a substantially V shape.

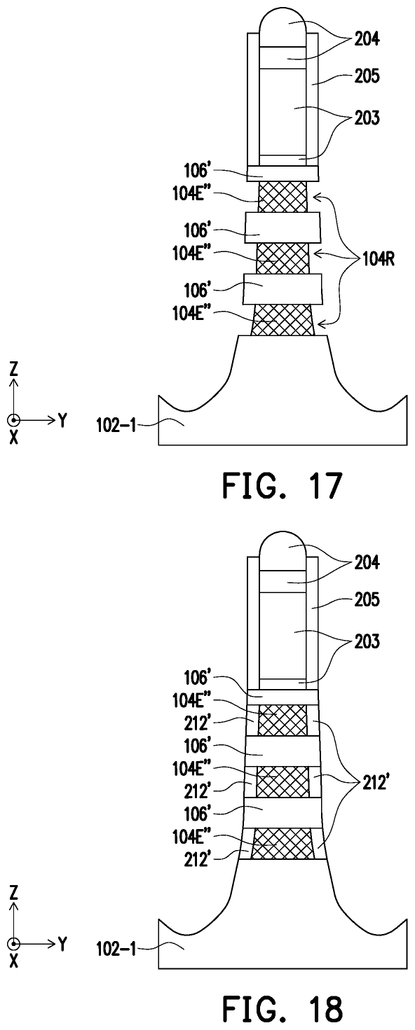

Referring to FIGS. 17-18 and with reference to FIG. 16 and FIGS. 7-8, portions of the first semiconductor layers 104 exposed by the recesses 100-1R may be removed in the lateral direction to form the etched first semiconductor layers 104E″ and the respective lateral recess 104R surrounding the corresponding etched first semiconductor layer 104E″. The lateral recessing process is similar to the process described in FIG. 7. Next, inner spacers 212′ may be formed in the lateral recesses 104R. For example, the inner spacers 212′ are formed along the etched ends of each of the etched first semiconductor layers 104E″ and along respective ends (along the Y-direction) of each of the etched first semiconductor layers 104E′ and the second semiconductor layers 106′. The forming process and the material of the inner spacers 212′ are similar to those of the inner spacers 212 described in FIG. 8.

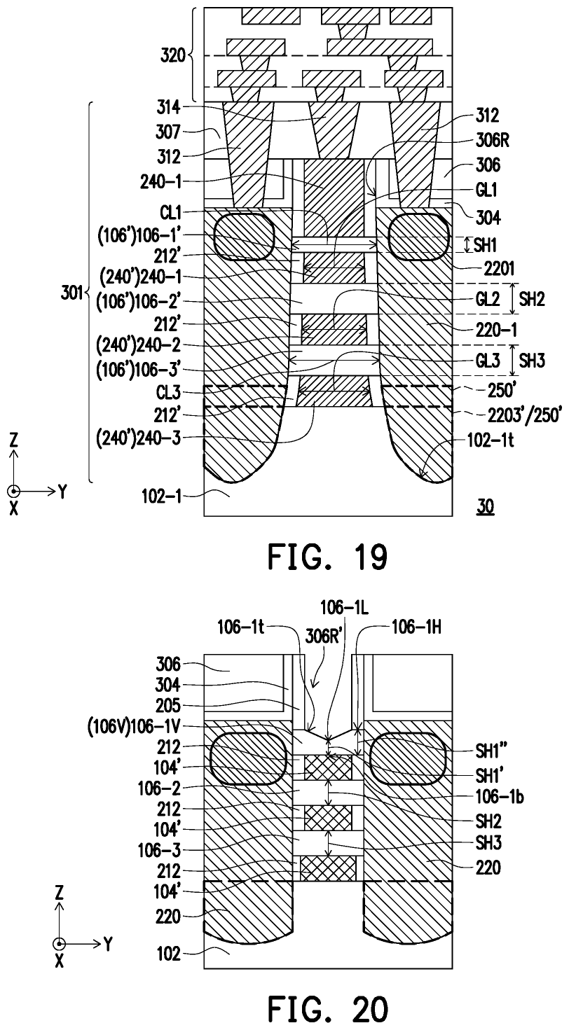

Referring to FIG. 19 and with reference to FIG. 18 and FIGS. 9-14, after forming the inner spacers 212′, the following steps may be similar to the processes described in FIGS. 9-14. For example, the epitaxial structures 220-1 may be epitaxially grown on the semiconductor substrate 102-1 and may have the bottom surfaces conformally coupled to the exposed top surfaces 102-1t of the semiconductor substrate 102-1. The respective epitaxial structure 220-1 optionally includes the first region 2201 laterally adjacent to the topmost second semiconductor layer 106-1′ and the third region 2203′ at the bottom of the epitaxial structure 220-1. In some embodiments, before forming the epitaxial structures 220-1, the bottom isolation structures 250′ are formed on the top surfaces 102-1t of the semiconductor substrate 102-1 as mentioned in FIG. 15. In some embodiments, the undoped epitaxial structures are formed on the top surfaces 102-1t of the semiconductor substrate 102-1, and then the bottom isolation structures 250′ are formed on the undoped epitaxial structures as mentioned in FIG. 15.

After forming the epitaxial structures 220-1, the etch stop layer 304, the first ILD layer 306 may be sequentially formed, and then the recess 306R accessibly revealing the topmost second semiconductor layer 106-1′ may be formed. Next, the etched first semiconductor layers 104E′ may be removed, and then the gate structures 240′ may be formed in the space where the topmost second semiconductor layer 106-1′ was formed and may also fill the recess 306R. Next, the second ILD layer 307 may be formed on the first ILD layer 306, and then the S/D contacts 312 and the gate contact 314 are formed to be respectively coupled to the epitaxial structures 220-1 and the topmost gate structure 240′. Sequentially, the front-side interconnect structure 320 may be formed on the second ILD layer 307, the S/D contacts 312, and the gate contact 314.

With continued reference to FIG. 19 and FIG. 14, a semiconductor device 30 including the device layer 301 formed in/on the semiconductor substrate 102-1 and the front-side interconnect structure 320 formed on the device layer 301 is provided. The difference between the semiconductor device 30 and the semiconductor device 10 illustrated in FIG. 14 includes the cross-sectional profiles of the epitaxial structures 220-1, the channel layers 106′, the gate structures 240′, and the inner spacers 212′. For example, the bottom of the respective epitaxial structure 220-1 (e.g., the third region 2203′) has the V-shaped cross-sectional profile, and the outer sidewall of the respective epitaxial structure 220-1 coupled to the outer sidewalls of the channel layers 106′ and the outer sidewalls of the inner spacers 212′ may be non-vertical. In some embodiments, the outer sidewalls of the gate structures 240′ coupled to the inner sidewalls of the inner spacers 212′ are non-vertical (e.g., slanted). In some embodiments, at least the bottommost gate structure 240-3 has the trapezoidal cross-sectional profile having a wider bottom than top.

The channel layers 106′ may become narrower (along the Y-direction) from the top to the bottom. For example, a length GL1 (along the Y-direction) of the topmost channel layer 106-1′ is less than a length GL3 of the bottommost channel layer 106-3′, and the S/D distance of the topmost channel layer 106-1′ may be smaller than that of the bottommost channel layer 106-3′. In some embodiments, the gate structure 240-1 underlying the topmost channel layer 106-1′ has a gate length GL1 (along the Y-direction) less than a gate length GL2 of the underlying gate structure 240-2. In some embodiments, the gate length GL2 is less than a gate length GL3 of the bottommost gate structure 240-3. The bottommost gate structure 240-3 may have the greatest gate length GL3 among the gate structures 240′, and the gate length GL1 may be the shortest among the gate lengths GL1, GL2, and GL3. It is appreciated that a shorter gate length may be more susceptible to short-channel effects. The topmost second semiconductor layer 106-1′ may be configured to have the thickness SH1 less than the thickness SH2 of the middle second semiconductor layer 106-2′ and also less than the thickness SH3 of the bottommost second semiconductor layer 106-3′ in order to control short channel effects.

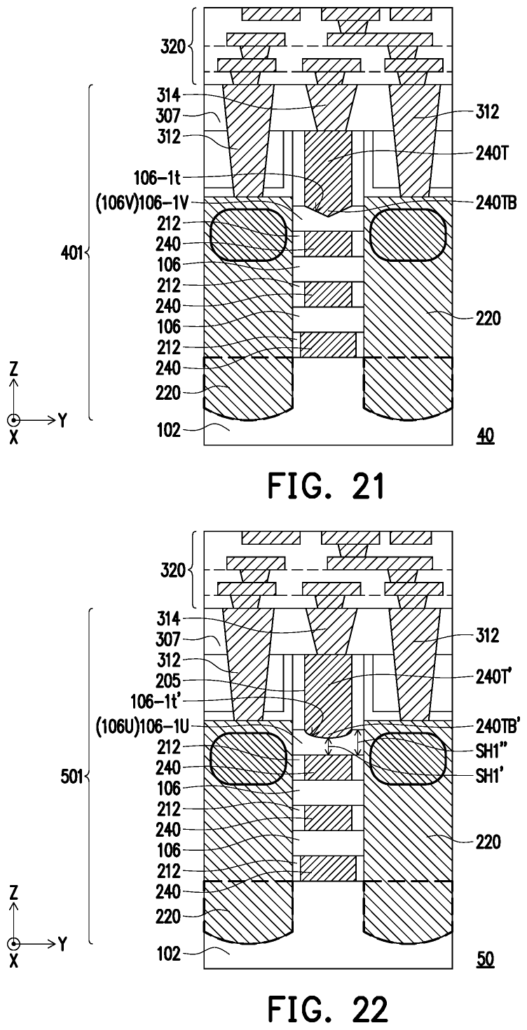

FIGS. 20-21 illustrate schematic cross-sectional views of intermediate steps during a process for forming a semiconductor device, in accordance with some embodiments. Unless specified otherwise, like reference numerals in this embodiment represent like components in the embodiment shown in FIGS. 1 through 14 formed by like processes. Accordingly, the process steps and applicable materials may not be repeated herein. In addition, although FIGS. 20-21 are described as a series of acts, these acts are not limiting in that the order of the acts can be altered in other embodiments, and the methods disclosed are also applicable to other structures. Alternatively, some acts that are illustrated and/or described may be omitted in whole or in part.

Referring to FIG. 20 and with reference to FIG. 11, the structure shown in FIG. 20 is similar to the structure shown in FIG. 11, except that the shape of the recess 306R and the shape of the topmost second semiconductor layer 106-1V. One or more removal processes may be performed to form the recess 306R′. For example, the removal processes may include the planarization process, the etching process(es), and a trimming process, where the planarization and etching processes are similar to the processes described in FIG. 11. The trimming process (e.g., wet etching) may be performed to recess the top surface of the topmost second semiconductor layer 106-1V, so that the top surface 106-1t of the topmost second semiconductor layer 106-1V may have a V-shaped (resembling the letter “V”) cross-sectional profile. For example, the top surface 106-1t includes a lowest point 106-1L, where tilted facets converge.

In some embodiments, the lowest point 106-1L of the top surface 106-1t is located at the center of the top surface 106-1t in the X-Y plane, and the V-shaped cross-sectional profile of the top surface 106-1t may be a symmetrical profile with respective to a virtual axis passing through the center of the top surface 106-1t (or the lowest point 106-1L) in the cross-sectional view. In some embodiments, the lowest point 106-1L of the top surface 106-1t is laterally offset from the center of the top surface 106-1t in the X-Y plane, and the V-shaped cross-sectional profile of the top surface 106-1t may be an asymmetric profile. The topmost second semiconductor layer 106-1V may have a variable thickness. For example, a first thickness SH1′ measured vertically between the lowest point 106-1L and the bottom surface 106-1b is less than a second thickness SH1″ measured vertically between a highest point 106-1H and the bottom surface 106-1b. In some embodiments, the highest point 106-1H is exposed by the recess 306R′ and will be subsequently coupled to the topmost gate structure. In some embodiments, the highest point 106-1H is directly under the gate spacer 205. In some embodiments, the second thickness SH1″ is the thickness of the edge of the topmost channel layer. In some embodiments, the difference between the second thickness SH1″ and the first thickness SH1′ is in a range of about 0.5 nm to about 4.0 nm, although other differences are within the contemplated scope of the disclosure. For example, the first thickness SH1′ is less than the thickness SH2 of the middle second semiconductor layer 106-2 and is also less than the thickness SH3 of the bottommost second semiconductor layer 106-3.

Referring to FIG. 21 and with reference to FIG. 20 and FIGS. 12-14, after recessing the topmost second semiconductor layer 106-1V, the following steps may be similar to the processes described in FIGS. 12-14. For example, the etched first semiconductor layers 104′ are replaced with the gate structures 240. The recess 306R′ may be filled with the topmost gate structure 240T, and thus the topmost gate structure 240T may have a bottom portion 240 TB that takes on the profile of the recess 306R′ (e.g., V-shaped). For example, the bottom portion 240 TB is wider at its top and becomes narrower toward the topmost second semiconductor layer 106-1V. Next, the second ILD layer 307 may be formed on the first ILD layer 306, and then the S/D contacts 312 and the gate contact 314 are formed to be respectively coupled to the epitaxial structures 220 and the topmost gate structure 240T. Sequentially, the front-side interconnect structure 320 may be formed on the second ILD layer 307, the S/D contacts 312, and the gate contact 314. It should be understood that the bottom isolation structures are optionally disposed on/over the semiconductor substrate as mentioned in FIG. 15.

With continued reference to FIG. 21 and FIG. 14, a semiconductor device 40 including the device layer 401 formed in/on the semiconductor substrate 102 and the front-side interconnect structure 320 formed on the device layer 401 is provided. The difference between the semiconductor device 40 and the semiconductor device 10 illustrated in FIG. 14 includes the cross-sectional profiles of the topmost gate structure 240T and the topmost channel layer 106-1V. As mentioned in FIG. 20, the topmost channel layer 106-1V may have the first thickness SH1′ less than the thicknesses SH2 and SH3 in order to control short channel effects. As compared to the topmost channel layer 106-1 in the semiconductor device 10 which is formed by super-lattice deposition and have a substantially flat top surface, the topmost channel layer 106-1V in the semiconductor device 40 may have a variable thickness gradually increasing from the central region of the top surface 106-1t toward the peripheral region of the top surface 106-1t. The topmost gate structure 240T formed on the top surface 106-1t of the topmost channel layer 106-1V may have the bottom surface overlying the top surface 106-1t in a conformal manner and may have a substantially triangular bottom portion.

FIG. 22 illustrates a schematic cross-sectional view of a semiconductor device, in accordance with some embodiments. Unless specified otherwise, like reference numerals in this embodiment represent like components in the embodiment shown in FIGS. 20-21. Referring to FIG. 22 and with reference to FIG. 21, a semiconductor device 50 including the device layer 501 formed in/on the semiconductor substrate 102 and the front-side interconnect structure 320 formed on the device layer 501 is provided. The difference between the semiconductor device 50 and the semiconductor device 40 illustrated in FIG. 21 includes the cross-sectional profiles of the topmost gate structure 240T′ and the topmost channel layer 106-1U.

In some embodiments, the top surface 106-1t′ of the topmost channel layer 106-1U has a U-shaped (resembling the letter “U”) cross-sectional profile. For example, a trimming process (e.g., dry etching) may be performed on the topmost second semiconductor layer after removing the dummy gate structure as described in FIG. 11. The topmost channel layer 106-1U may be etched to become U-shaped, so that the top surface 106-1t′ thus become curved, rather than substantially straight. The topmost second semiconductor layer 106-1U may have a variable thickness. For example, the first thickness SH1′ of the topmost channel layer 106-1U in the central region is less than the second thickness SH1″ of the topmost channel layer 106-1U in the peripheral region. In some embodiments, the second thickness SH1″ is the thickness of the edge of the topmost channel layer 106-1U. In some embodiments, the difference between the second thickness SH1″ and the first thickness SH1′ is in a range of about 0.5 nm to about 4.0 nm, although other differences are within the contemplated scope of the disclosure.

The top edges of the U-shaped top surface 106-1t′ may be joined to the opposing sidewalls of the gate spacer 205. The topmost gate structure 240T′ formed on the topmost channel layer 106-1U may have a U-shaped bottom surface overlying the top surface 106-1t′ in a conformal manner. For example, the topmost gate structure 240T′ may have rounded bottom corners adjoining the topmost channel layer 106-1U and the gate spacer 205. It should be understood that the top surface of the topmost channel layer may be V-shaped, U-shaped, or have another shape so long as the topmost channel layer is thinner than the bottommost channel layer or the topmost channel layer is the thinnest among the channel layers in order to control short channel effects.

According to some embodiments, a semiconductor device includes semiconductor nanosheets vertically stacked upon one another and disposed above a semiconductor substrate, a gate structure surrounding each of the semiconductor nanosheets, and source/drain regions disposed over the semiconductor substrate and laterally abutting the semiconductor nanosheets. The semiconductor nanosheets serve as channel regions, and a topmost semiconductor nanosheet most distanced from the semiconductor substrate is thinner than an underlying semiconductor nanosheet between the topmost semiconductor nanosheet and the semiconductor substrate.

According to some alternative embodiments, a semiconductor device includes a semiconductor substrate and a device layer disposed on the semiconductor substrate. The device layer includes channel regions vertically stacked upon one another, a gate structure surrounding each of the channel regions, and S/D regions laterally coupled to the channel regions and laterally separated from the gate structure. A thickness of a topmost channel region is less than that of a bottommost channel region.

According to some alternative embodiments, a manufacturing method for a semiconductor device includes forming semiconductor nanosheets over a semiconductor substrate, wherein the semiconductor nanosheets are vertically stacked upon and separate apart from one another, and a topmost semiconductor nanosheet most distanced from the semiconductor substrate is thinner than an underlying semiconductor nanosheet between the topmost semiconductor nanosheet and the semiconductor substrate; forming epitaxial structures on the semiconductor substrate, wherein the epitaxial structures are laterally coupled to the semiconductor nanosheets; and forming a gate structure around the semiconductor nanosheets after forming the epitaxial structures, wherein each of the semiconductor nanosheets is wrapped around by the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
semiconductor nanosheets vertically stacked upon one another, disposed above a semiconductor substrate, and serving as channel regions, wherein a topmost semiconductor nanosheet most distanced from the semiconductor substrate is thinner than an underlying semiconductor nanosheet between the topmost semiconductor nanosheet and the semiconductor substrate;
a gate structure surrounding each of the semiconductor nanosheets; and
source/drain (S/D) regions disposed over the semiconductor substrate and laterally abutting the semiconductor nanosheets.

2. The semiconductor device of claim 1, wherein each of the S/D regions comprises:
a first region laterally adjacent to the topmost semiconductor nanosheet; and
a second region below the first region, wherein a doping concentration in the first region is higher than a doping concentration in the second region.

3. The semiconductor device of claim 1, wherein a top segment of the gate structure directly under the topmost semiconductor nanosheet comprises a gate length less than a gate length of a bottom segment of the gate structure directly under a bottommost semiconductor nanosheet.

4. The semiconductor device of claim 1, wherein:
top portions of adjacent two of the S/D regions are disposed at opposing sides of the topmost semiconductor nanosheet,
bottom portions of the adjacent two of the S/D regions are disposed at opposing sides of a bottommost semiconductor nanosheet, and
a lateral distance between the top portions of the adjacent two of the S/D regions is less than a lateral distance between the bottom portions of the adjacent two of the S/D regions.

5. The semiconductor device of claim 1, wherein a top surface of the topmost semiconductor nanosheet comprises a substantially V-shaped cross-sectional profile or a substantially U-shaped cross-sectional profile.

6. The semiconductor device of claim 1, wherein a top surface of the topmost semiconductor nanosheet comprises an asymmetric profile in a cross-sectional view.

7. The semiconductor device of claim 1, wherein the topmost semiconductor nanosheet comprises a first thickness in a central region and a second thickness in a peripheral region, and the first thickness is less than the second thickness.

8. The semiconductor device of claim 1, further comprising:
a bottom isolation structure disposed on the semiconductor substrate to isolate the S/D regions from the semiconductor substrate.

9. The semiconductor device of claim 1, further comprising:
an undoped epitaxial structure directly disposed on the semiconductor substrate; and
a bottom isolation structure overlying the undoped epitaxial structure, wherein the S/D regions are directly on the bottom isolation structure.

10. A semiconductor device, comprising:
a semiconductor substrate; and
a device layer disposed on the semiconductor substrate, the device layer comprising:
channel regions vertically stacked upon one another, wherein a thickness of a topmost channel region is less than that of a bottommost channel region;
a gate structure surrounding each of the channel regions; and
S/D regions laterally coupled to the channel regions and laterally separated from the gate structure.

11. The semiconductor device of claim 10, wherein the semiconductor substrate comprising a p-type region and an n-type region, and the thickness of the topmost channel region corresponding to the p-type region is different from the thickness of the topmost channel region corresponding to the n-type region.

12. The semiconductor device of claim 10, wherein each of the S/D regions comprises:
a first region laterally adjacent to the topmost channel regions; and
a second region other than the first region, wherein a doping concentration in the first region is higher than a doping concentration in the second region.

13. The semiconductor device of claim 10, further comprising:
inner spacers laterally interposed between the gate structure and the S/D regions; and
a bottom isolation structure disposed on the semiconductor substrate and laterally adjoining a bottommost one of the inner spacers.

14. A manufacturing method for a semiconductor device, comprising:
forming semiconductor nanosheets over a semiconductor substrate, wherein the semiconductor nanosheets are vertically stacked and separate apart from one another, and a topmost semiconductor nanosheet most distanced from the semiconductor substrate is thinner than an underlying semiconductor nanosheet between the topmost semiconductor nanosheet and the semiconductor substrate;
forming epitaxial structures on the semiconductor substrate, wherein the epitaxial structures are laterally coupled to the semiconductor nanosheets; and
forming a gate structure around the semiconductor nanosheets after forming the epitaxial structures, wherein each of the semiconductor nanosheets is wrapped around by the gate structure.

15. The manufacturing method of claim 14, wherein forming the semiconductor nanosheets over the semiconductor substrate comprises:
depositing a stack of the semiconductor nanosheets over the semiconductor substrate, wherein the topmost semiconductor nanosheet in the stack is deposited to be thinner than the underlying semiconductor nanosheet in the stack.

16. The manufacturing method of claim 14, wherein forming the semiconductor nanosheets over the semiconductor substrate comprises:
recessing a top surface of the topmost semiconductor nanosheet after forming the epitaxial structures and before forming the gate structure, wherein the top surface of the topmost semiconductor nanosheet comprises a substantially V-shaped cross-sectional profile or a substantially U-shaped cross-sectional profile.

17. The manufacturing method of claim 14, wherein forming the semiconductor nanosheets over the semiconductor substrate and forming the epitaxial structures on the semiconductor substrate comprise:
forming a stack of semiconductor layers and sacrificial semiconductor layers alternatively formed on top of one another;
forming a trench in the stack to form a fin structure, wherein the fin structure comprises alternatively stacked the semiconductor nanosheets and sacrificial semiconductor nanosheets, and a lateral dimension of the stack gradually increases from a top of the fin structure toward a bottom of the structure; and
growing the epitaxial structures on the semiconductor substrate and in the trench to be laterally coupled to the fin structure.

18. The manufacturing method of claim 17, wherein forming the gate structure comprises:
removing the sacrificial semiconductor nanosheets to form recesses; and
forming the gate structure in the recesses, wherein a top segment of the gate structure directly under the topmost semiconductor nanosheet comprises a gate length less than a gate length of a bottom segment of the gate structure directly under a bottommost semiconductor nanosheet.

19. The manufacturing method of claim 14, wherein forming the epitaxial structures on the semiconductor substrate comprises:
growing an epitaxial layer on the semiconductor substrate to form the epitaxial structures, wherein each of the epitaxial structures comprises a first region with a doping concentration higher than a second region other than the first region.

20. The manufacturing method of claim 14, wherein before forming the epitaxial structures on the semiconductor substrate, the manufacturing method further comprises:
forming a bottom isolation structure on the semiconductor substrate, wherein the epitaxial structures are formed on the bottom isolation structure.
